(19) United States
(12) Patent Application Publication
(10) Pub. No.: US 2011/0233632 A1
(43) Pub. Date: Sep. 29, 2011

(54) SEMICONDUCTOR SEAL-RING STRUCTURE AND THE MANUFACTURING METHOD THEREOF

(75) Inventors: Kuo-Chiang Chen, Taipei County (TW); Yen-Yi Chen, Sanchong City (TW)

(73) Assignee: FORTUNE SEMICONDUCTOR CORPORATION, TAIPEI HSIEN (TW)

(21) Appl. No.: 12/749,497

(22) Filed: Mar. 29, 2010

(51) Int. Cl. H01L 27/10; H01L 21/02; H01L 21/336

(52) U.S. Cl. 257/300; 438/239; 257/E27.071; 257/E21.008; 257/E21.409

(57) ABSTRACT

A seal-ring structure includes a substrate, a source/drain layer, a first dielectric layer, a first lower metal layer, a gate layer and a second lower metal layer. The source/drain layer is disposed within the substrate. The first dielectric layer is disposed over the substrate. The first lower metal layer is disposed over the first dielectric layer and coupled to the source/drain layer via a first contact. The gate layer is disposed within the first dielectric layer. The second lower metal layer is disposed over the first dielectric layer and coupled to the gate layer via a second contact.

### BACKGROUND OF THE INVENTION

1. Field of the Invention

The present invention relates to a semiconductor seal-ring structure and a manufacturing method, and more particularly, to the semiconductor seal-ring structure with a capacitive effect formed within a semiconductor chip, and a manufacturing method of the seal-ring structure.

2. Description of the Related Art

Reference is made to FIG. 1, which shows a vertical view of a semiconductor chip of the prior art. The semiconductor chip 1 includes an integrated circuit region 10 and a seal-ring 12 around the integrated circuit region 10. The integrated circuit region 10 includes various electronic components such as active components and passive components. Moreover, the seal-ring 12 is used to prevent the electrostatic discharge from entering into the integrated circuit region 10, and avoid any damage to the integrated circuit region 10 caused by a wafer cutting machine, and isolate the integrated circuit region 10 from vapors, pollutants and corrosives.

Reference is made to FIG. 2, which shows a circuit diagram of a semiconductor chip of the prior art. In general, the semiconductor chip 1 may have to connect to an external capacitor C1 for stabilizing an input voltage Vcc, which is received through a voltage input pin Vdd, adding an additional cost to the manufacturing of the semiconductor chip and complicating a circuitry of the semiconductor chip 1.

### SUMMARY OF THE INVENTION

One particular aspect of the present invention is to provide a semiconductor chip seal-ring structure and a manufacturing method for the semiconductor seal-ring structure. The seal-ring structure of the semiconductor chip provides a capacitor within the semiconductor chip for eliminating the need of an external capacitor C1 while stabilizing inputted voltage for the semiconductor chip.

The seal-ring structure of the present invention includes a substrate, a source/drain layer, a first dielectric layer, a first lower metal layer, a gate layer and a second lower metal layer. The source/drain layer is disposed within the substrate. The first dielectric layer is disposed over the substrate, wherein the first dielectric layer has a first contact and a second contact. The first lower metal layer is disposed over the first dielectric layer and coupled to the source/drain layer via the first contact. The gate layer is disposed within the first dielectric layer. The second lower metal layer is disposed over the first dielectric layer and coupled to the gate layer via the second contact.

The manufacturing method of the seal-ring structure of the present invention includes steps of preparing a substrate, forming a source/drain layer within the substrate, forming a first dielectric layer over the substrate, forming a gate layer within the first dielectric layer, and forming a first lower metal layer over the first dielectric layer, wherein the first lower metal layer couples to the source/drain layer via a first contact, and forming a second lower metal layer over the first dielectric layer, wherein the second lower metal layer couples to the gate layer via a second contact.

The seal-ring structure provides a capacitor between the first lower metal layer and the second lower metal layer and between the first contact and the second contact. Moreover, the gate layer serves as a first electrode of the capacitor and the source/drain layer is a second electrode of the capacitor. Therefore, with the capacitor formed between an input voltage pin and a ground pin of the semiconductor chip of the present invention the inputted voltage received through the input voltage pin could still be stabilized even without the placement of an external capacitor outside of the semiconductor chip.

For further understanding of the invention, reference is made to the following detailed description illustrating the embodiments and examples of the invention. The description is only for illustrating the invention and is not intended to limit of the scope of the claim.

### BRIEF DESCRIPTION OF THE DRAWINGS

The drawings included herein provide a further understanding of the invention. A brief introduction of the drawings is as follows:

FIG. 1 shows a vertical view of a semiconductor chip of the prior art;

FIG. 2 shows a circuit diagram of a semiconductor chip of the prior art;

FIG. 3 shows a vertical view of a semiconductor chip in accordance with one embodiment of the present invention;

FIG. 4 shows a circuit diagram of a semiconductor chip in accordance with one embodiment of the present invention;

FIG. 5 shows a schematic diagram enlarging a part of a seal-ring structure in accordance with one embodiment of the present invention;

FIG. 6 shows a cross-sectional view of a seal-ring structure in accordance with one embodiment of the present invention; and

FIG. 7 shows a flow chart of manufacturing a seal-ring structure in accordance with one embodiment of the present invention.

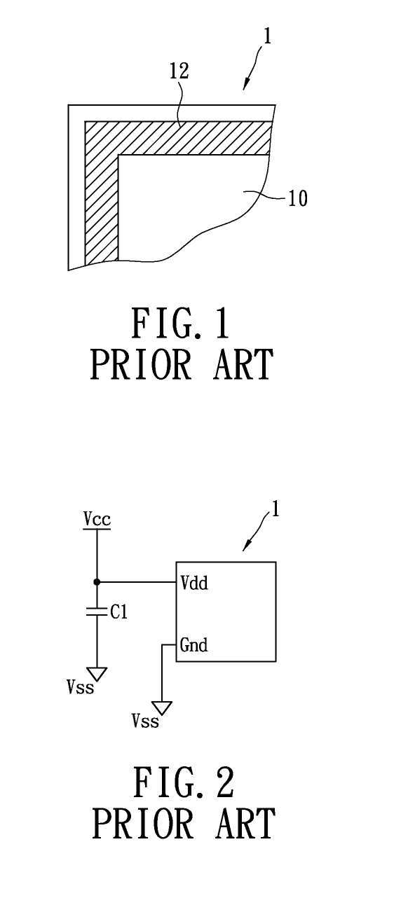

### DETAILED DESCRIPTION OF THE PREFERRED EMBODIMENTS

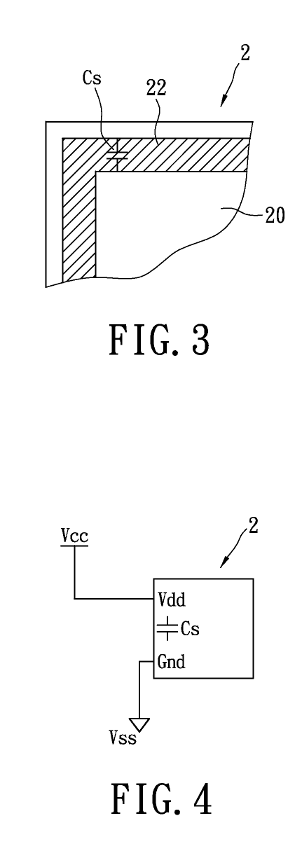

Please refer to FIG. 3. FIG. 3 shows a vertical view of a semiconductor chip in accordance with one embodiment of the present invention. A conductor chip 2 has a seal-ring structure 22 disposed around an integrated circuit region 20. The seal-ring structure 22 is configured to prevent the electrostatic discharge from entering into the integrated circuit region 20, avoid the damage to the integrated circuit region 20 caused by the wafer cutting machine, and isolate the integrated circuit region 20 from vapors, pollutants, and corrosives. The seal-ring structure 22 is also configured to form a capacitor Cs. And the capacitor Cs is formed between an input voltage pin and a ground pin of the semiconductor chip 2.

In conjunction with FIG. 3, FIG. 4 shows a circuit diagram of a semiconductor chip in accordance with one embodiment of the present invention. The semiconductor chip 2 includes a ground pin Gnd connected to a low voltage source Vss, and a input voltage pin Vdd connected to an external voltage source Vcc, which is a high voltage source. Since the capacitor Cs could be formed between the input voltage pin and the ground pin, no external capacitor such as C1 in FIG. 2 is necessary without destabilizing the inputted voltage received through the input voltage pin.

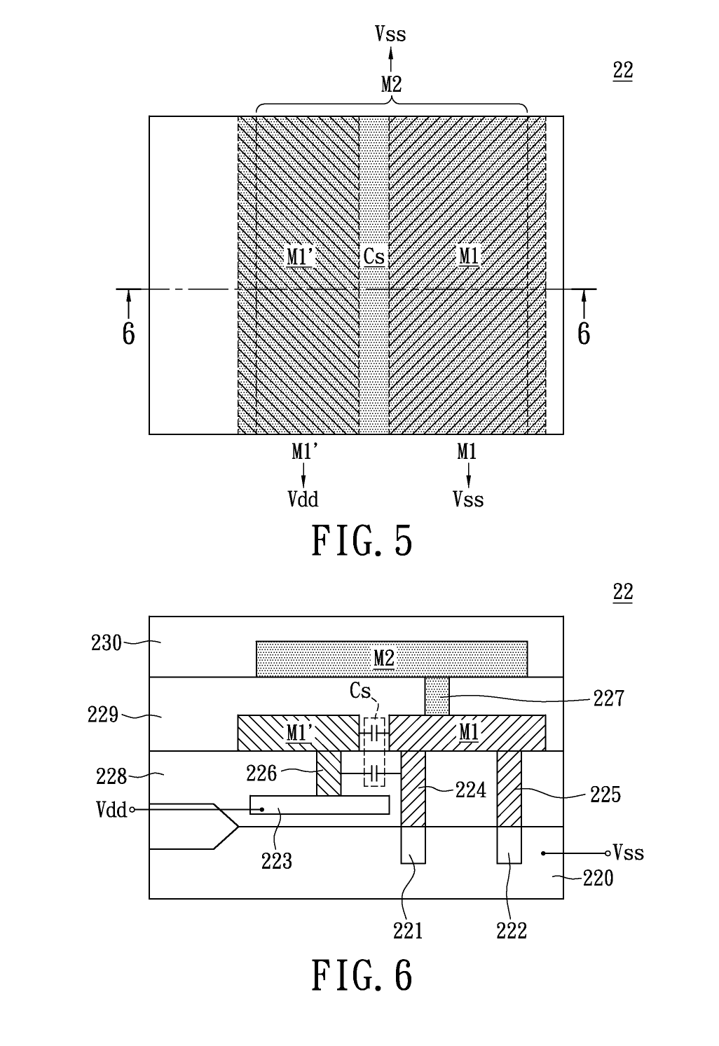

Please refer to FIG. 5 showing a schematic diagram enlarging a part of a seal-ring structure in accordance with one embodiment of the present invention. The seal-ring structure 22 includes a first lower metal layer M1, a second lower metal layer M1′ and an upper metal layer M2, wherein the first lower metal layer M1 and the second lower metal layer M1′ are disposed on a substantially the same plane. Moreover, the upper metal layer M2 is disposed over the first lower metal layer M1 and the second lower metal layer M1′. Furthermore, a capacitor Cs is formed between the first lower metal layer M1 and the second lower metal layer M1′.

The seal-ring structure 22, the first lower metal layer M1 and the upper metal layer M2 are coupled to the low voltage source Vss while the second lower metal layer M1′ is coupled to the high voltage source Vdd.

Please refer to FIG. 6 of a cross-sectional view of a seal-ring structure in accordance with one embodiment of the present invention. The seal-ring structure 22 includes a substrate 220, a source/drain layer (221, 222), a first dielectric layer 228, a first lower metal layer M1, a gate layer 223 and a second lower metal layer M1′. In one implementation, the substrate 220 is a P type substrate. Moreover, the source/drain layer 221/222 is disposed within the substrate 220. The source/drain layer 221/222 is a doped layer. And the source/drain layer 221 and 222 could be a N type doped layer or P type doped layer. Furthermore, the first dielectric layer 228 is disposed over the substrate 220. The material of the first dielectric layer 228 could be selected from a group including but not limited to SiO2, Si3N4, SiOxNy, spin on glass (SOG) or low-K material.

The first dielectric layer 228 has a first contact 224/225 and a second contact 226. The first lower metal layer M1 is disposed over the first dielectric layer 228 and coupled to the source/drain layer 221/222 via the first contact 224/225. Moreover, the gate layer 223 is disposed within the first dielectric layer 228. The second lower metal layer M1′ is disposed over the first dielectric layer 228 and coupled to the gate layer 223 via the second contact 226. In one implementation, the gate layer 223 is a poly-silicon layer.

In the seal-ring structure 22, a capacitor Cs is formed between the first lower metal layer M1 and the second lower metal layer M1′ and between the first contact 224/225 and the second contact 226. Moreover, the source/drain layer 221/222 is a first electrode of the capacitor Cs, and the gate layer 223 is a second electrode of the capacitor Cs. Furthermore, the first electrode of the capacitor Cs is used to couple to the low voltage source Vss, and the second electrode of the capacitor Cs is used to couple to the high voltage source Vdd.

The seal-ring structure 22 further comprises a second dielectric layer 229, an upper metal layer M2, and a protection layer 230. The second dielectric layer 229 is disposed over the first lower metal layer M1 and the second lower metal layer M1′. The second dielectric layer 229 has a third contact, and the material of the second dielectric layer 229 could be selected from a group including but not limited to SiO2, Si3N4, SiOxNy, spin on glass (SOG) or low-K material. Moreover, the upper metal layer M2 is disposed over the second dielectric layer 229 and coupled to the first lower metal layer M1 via the third contact 227. The protection layer 230 is disposed over the upper metal layer M2. Furthermore, the protection layer 230 is the top layer of the seal-ring structure 22, and thus is configured to minimize any potential damage or pollution that could have taken place on the surface of the seal-ring structure 22.

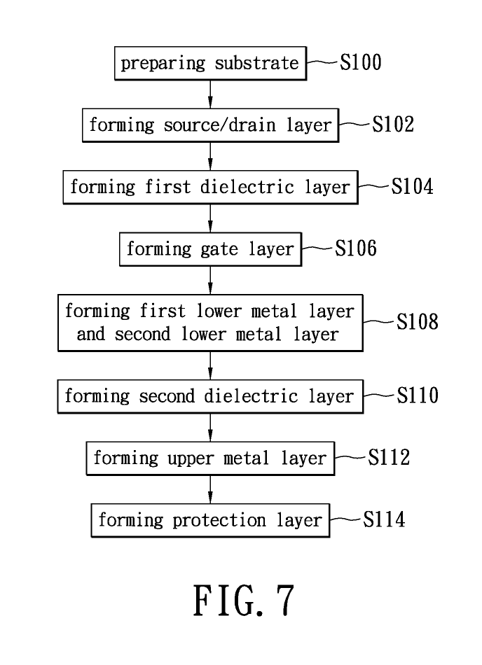

In conjunction with FIG. 6, FIG. 7 shows a flow chart of manufacturing a seal-ring structure in accordance with one embodiment of the present invention. In step S100, the method prepares a substrate 220. In step S102, the method forms a source/drain layer 221/222 within the substrate 220. In step S104, the method forms a first dielectric layer 228 over the substrate 220. In step S106, the method prepares a gate layer 223 within the first dielectric layer 228. In step S108, the method further prepares a first lower metal layer M1 and a second lower metal layer M1′ over the first dielectric layer 228, wherein the first lower metal layer M1 is coupled to the source/drain layer 221/222 via a first contact 224/225, and the second lower metal layer M1′ is coupled to the gate layer 223 via a second contact 226.

The manufacturing method of seal-ring structure 22 further includes step S110 in which a second dielectric layer 229 is formed over the first lower metal layer M1 and the second lower metal layer M1′. In step S112, the manufacturing method forms an upper metal layer M2 over the second dielectric layer 229, wherein the upper metal layer M2 is coupled to the first lower layer M1 via a third contact 227. In step S114, the manufacturing method forms a protection layer over the upper metal layer M2. Moreover, both the first dielectric layer 228 and the second dielectric layer 229 could be selected from a group including but not limited to SiO2, Si3N4, SiOxNy, spin on glass (SOG) or low-K material.

The manufacturing of the contacts 224, 225, 226, 227 could be including forming holes within the dielectric layers 228, 229, depositing the metal material (such as Ti, W, Al, Ag, Cu or alloy) within the dielectric layers 228, 229 and filling the metal material into the holes by physical vapor depositing (PVD) or chemical vapor depositing (CVD), and etching the metal material other than that within the holes wherein the un-etched metal material serves as the contacts 224, 225, 226, 227.

To sum up, the seal-ring structure 22 according to the manufacturing method of the present invention provides the capacitor Cs formed between the first lower metal layer M1 and the second lower metal layer M1′ and between the first contact 224/225 and the second contact 226. Furthermore, the source/drain layer 221/222 of the seal-ring structure 22 is used to be a first electrode of the capacitor Cs, and the gate layer 223 of the seal-ring structure 22 is used to be a second electrode of the capacitor Cs. The first electrode of the capacitor Cs is used to couple to the low voltage source Vss, and the second electrode of the capacitor Cs is used to couple to the high voltage source Vdd.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A seal-ring structure, comprising:
a substrate;
a source/drain layer disposed within the substrate;
a first dielectric layer disposed over the substrate, wherein the first dielectric layer has a first contact and a second contact;
a first lower metal layer disposed over the first dielectric layer and coupled to the source/drain layer via the first contact;
a gate layer disposed within the first dielectric layer; and
a second lower metal layer disposed over the first dielectric layer and coupled to the gate layer via the second contact.

2. The seal-ring structure as claimed in claim 1, wherein a capacitor is formed between the first lower metal layer and the second lower metal layer and between the first contact and the second contact.

3. The seal-ring structure as claimed in claim 2, wherein the source/drain layer is a first electrode of the capacitor.

4. The seal-ring structure as claimed in claim 3, wherein the source/drain layer is a doped layer.

5. The seal-ring structure as claimed in claim 4, wherein the doped layer is a N-type type doped layer or a P-type doped layer.

6. The seal-ring structure as claimed in claim 3, wherein the first electrode couples to a low voltage source.

7. The seal-ring structure as claimed in claim 2, wherein the gate layer is a second electrode of the capacitor.

8. The seal-ring structure as claimed in claim 7, wherein the gate layer is a poly-silicon layer.

9. The seal-ring structure as claimed in claim 7, wherein the second electrode couples to a high voltage source.

10. The seal-ring structure as claimed in claim 1, further comprising:
a second dielectric layer disposed over the first lower metal layer and the second lower metal layer, wherein the second dielectric layer has a third contact;
an upper metal layer disposed over the second dielectric layer and coupled to the first lower metal layer via the third contact; and
a protection layer disposed over the upper metal layer.

11. A manufacturing method of a seal-ring structure, comprising:
preparing a substrate;
forming a source/drain layer within the substrate
forming a first dielectric layer over the substrate;
forming a gate layer within the first dielectric layer;
forming a first lower metal layer over the first dielectric layer, wherein the first lower metal layer couples to the source/drain layer via a first contact; and
forming a second lower metal layer over the first dielectric layer, wherein the second lower metal layer couples to the gate layer via a second contact.

12. The manufacturing method as claimed in claim 11, further comprising:
forming a second dielectric layer over the first lower metal layer and the second lower metal layer; and
forming an upper metal layer over the second dielectric layer, wherein the upper metal layer couples to the first lower layer via a third contact.

13. The manufacturing method as claimed in claim 12, further comprising:
forming a protection layer over the upper metal layer.

14. A semiconductor chip, comprising:
an integrated circuit region;
a seal-ring disposed outside of and around the integrated circuit region, wherein the seal-ring comprises:
a substrate;
a source/drain layer disposed within the substrate;
a first dielectric layer disposed over the substrate, wherein the first dielectric layer has a first contact and a second contact;
a first lower metal layer disposed over the first dielectric layer and coupled to the source/drain layer via the first contact;
a gate layer disposed within the first dielectric layer; and
a second lower metal layer disposed over the first dielectric layer and coupled to the gate layer via the second contact.

15. The semiconductor chip as claimed in claim 14, further comprising:
a second dielectric layer disposed over the first lower metal layer and the second lower metal layer, wherein the second dielectric layer has a third contact;
an upper metal layer disposed over the second dielectric layer and coupled to the first lower metal layer via the third contact; and
a protection layer disposed over the upper metal layer.
